(19) United States
(12) Patent Application Publication
(10) Pub. No.: US 2016/0197207 A1
(43) Pub. Date: Jul. 7, 2016

(54) SOLAR CELL, SOLAR CELL MODULE, AND MANUFACTURING METHOD OF SOLAR CELL

(71) Applicant: Mitsubishi Electric Corporation, Chiyoda-ku (JP)

(72) Inventors: Takayuki MORIOKA, Tokyo (JP); Hirofumi KONISHI, Tokyo (JP); Tatsuro WATAHIKl, Tokyo (JP); Hiroya YAMARIN, Tokyo (JP); Hidetada TOKIOKA, Tokyo (JP)

(73) Assignee: Mitsubishi Electric Corporation, Chiyoda-ku (JP)

(21) Appl. No.: 14/962,842

(22) Filed: Dec. 8, 2015

(30) Foreign Application Priority Data
Dec. 9, 2014 (JP) 2014-248905
Nov. 27, 2015 (JP) 2015-232128

(51) Int. Cl. H01L 31/0224

(52) U.S. Cl. CPC H01L 31/022433

(57) ABSTRACT

A solar cell includes a p-type monocrystalline silicon substrate having first and second principal surfaces, an n-type diffusion layer formed on the first principal surface of the p-type monocrystalline silicon substrate, a plurality of grid electrodes formed on the n-type diffusion layer, a first collector electrode including a bus electrode that connects the grid electrodes to establish connection to the outside, and a second collector electrode formed on the second principal surface. The n-type diffusion layer has a lower impurity concentration in a first region surrounding the bus electrode than a second region away from the bus electrode.

### BACKGROUND OF THE INVENTION

1) Field of the Invention

The present invention relates to a solar cell in which an in-plane distribution of a collector resistance is adjusted, and to a solar cell module and a manufacturing method of a solar cell.

2) Description of the Related Art

Solar cells have been receiving attention as a next-generation power generation method because of a reduced environmental load or a low operating cost. As an example of the solar cells, there is a solar cell in which an n-type impurity diffusion layer is formed over the entire light-receiving surface of a polycrystalline or monocrystalline p-type silicon substrate to form a p-n junction, and microasperity referred to as “texture” is provided on the surface on the light-receiving surface side. An anti-reflective film is formed on the microasperity, and a comb-shaped collector electrode is provided thereon. A collector electrode is also provided on the entire back surface on the back surface side of the p-type silicon substrate.

As an example of a structure for improving photon-to-electron conversion efficiency of solar cells, there has been proposed a selective emitter structure as disclosed in Japanese Patent Application Laid-Open No. 2004-273829. In the selective emitter structure, in an impurity diffusion layer formed on the light-receiving surface, an emitter region having a surface impurity concentration higher than that of the surrounding area is selectively formed in the region connected to the collector electrode.

In other words, the selective emitter structure is a technique of changing the impurity concentration of an impurity diffusion layer formed in a region under an electrode on the light-receiving surface or the back surface and in a region other than under the electrode, thereby forming a diffusion layer suitable for each region. By having the selective emitter structure, the surface impurity concentration in the emitter region that comes into contact with the electrode can be increased in a state where the impurity concentration in a junction portion is maintained at an appropriate concentration, thereby reducing the ohmic contact resistance between the semiconductor substrate and the electrode so as to improve the fill factor. Furthermore, in the emitter region, the field effect in the region connected to the electrode increases because of the diffusion of impurities at a high concentration, to suppress recombination of photogenerated carriers in a light receiving portion, thereby enabling a high open voltage Voc to be acquired.

However, according to the conventional technique described above, although the fill factor can be improved, there has been a limitation on improvement. Therefore, as a result of various experiments, the present inventors have focused attention on a point that the voltage drop due to the distance to a current-collecting portion connected to a current-drawing lead, which is referred to as “tab wire”, prominently affects the limitation on improvement. The electrode on the light-receiving surface side of the solar cell is configured from current-collecting portions, such as grid electrodes distributed to the entire solar cell and bus electrodes connected to the grid electrodes. The present inventors have focused attention on the fact that, in the light receiving surface of the solar cell, a portion further away from the bus electrodes has a larger voltage drop due to the electrical resistance because the distance passing through the grid electrodes increases. Therefore, the difference in a current-voltage curve between a portion away from the bus electrodes and a portion close to the bus electrodes increases. As a result, the fill factor of the current-voltage curve decreases in the entire solar cell.

### SUMMARY OF THE INVENTION

An object of the present invention is to solve at least the problem described above.

In order to solve the above problems and achieve the object, an aspect of the present invention is a solar cell including: a first-conductivity-type semiconductor substrate having first and second principal surfaces; a second-conductivity-type impurity region formed on the first or second principal surface of the semiconductor substrate; a first collector electrode including a plurality of grid electrodes and a current-collecting portion, the grid electrodes being formed on the first-conductivity-type semiconductor substrate or the second-conductivity-type impurity region, the current-collecting portion connecting the grid electrodes to establish connection to an outside; and a second collector electrode formed on a side opposing the first collector electrode of the semiconductor substrate, wherein a sheet resistance of a first collector-electrode forming surface is higher in a first region surrounding the current-collecting portion than a second region away from the current-collecting portion.

The foregoing and other objects, characteristics, and advantages of the present invention will be made clear from the following detailed descriptions of the invention with reference to the accompanying drawings.

### BRIEF DESCRIPTION OF THE DRAWINGS

FIGS. 1A and 1B are diagrams schematically illustrating a solar cell according to a first embodiment of the present invention, where FIG. 1A is a plan view and FIG. 1B is a sectional view taken along line A-A in FIG. 1A;

FIG. 2 is a diagram illustrating current-voltage curves in a first region and a second region in a solar cell according to a comparative example for explaining the first embodiment of the present invention;

FIG. 3 is a diagram illustrating current-voltage curves in a first region and a second region in the solar cell according the first embodiment of the present invention;

FIGS. 4A to 4E are manufacturing process diagrams of the solar cell according to the first embodiment of the present invention;

FIG. 5 is a diagram illustrating the impurity concentration distribution in a second region 2D in a modification of the solar cell according to the first embodiment of the present invention;

FIGS. 6A to 6C are diagrams schematically illustrating a solar cell according to a second embodiment of the present invention, where FIG. 6A is a plan view, FIG. 6B is a sectional view taken along line B-B in FIG. 6A, and FIG. 6C is a sectional view taken along line C-C in FIG. 6A;

FIGS. 7A and 7B are diagrams schematically illustrating a solar cell according to a third embodiment of the present invention, where FIG. 7A is a plan view and FIG. 7B is a sectional view taken along line A-A in FIG. 7A;

FIGS. 8A and 8B are diagrams schematically illustrating a solar cell according to a fourth embodiment of the present invention, where FIG. 8A is a plan view and FIG. 8B is a sectional view taken along line A-A in FIG. 8A;

FIG. 9A is a top view schematically illustrating a structure of a solar cell module according to a fifth embodiment, and FIG. 9B is a sectional view illustrating the structure of the solar cell module according to the fifth embodiment;

FIG. 10 is a perspective view illustrating a part of a string in a solar cell module according to the fifth embodiment;

FIG. 11 is a diagram schematically illustrating a part of a string in a solar cell module according to a modification of the fifth embodiment;

FIGS. 12A to 12C are diagrams schematically illustrating a solar cell according to a sixth embodiment of the present invention, where FIG. 12A is a plan view, FIG. 12B is a sectional view taken along line A-A in FIG. 12A, and FIG. 12C is a diagram illustrating a distribution of a specific resistance of a semiconductor substrate; and

FIGS. 13A to 13C are diagrams schematically illustrating a solar cell according to a seventh embodiment of the present invention, where FIG. 13A is a plan view, FIG. 13B is a sectional view taken along line A-A in FIG. 13A, and FIG. 13C is a diagram illustrating a distribution of a specific resistance of a semiconductor substrate.

### DETAILED DESCRIPTION OF THE PREFERRED EMBODIMENTS

A solar cell and a manufacturing method of a solar cell according to embodiments of the present invention will be explained below in detail with reference to the accompanying drawings. The present invention is not limited to the embodiments, and the present invention can be modified as appropriate without departing from the scope thereof. In the drawings described below, for ease of understanding, scales of respective layers or respective members may be shown differently from the actuality, and the same is true for the relations between the drawings. In addition, even to plan views, hatchings may be applied in order to facilitate visualization of the drawings.

### First Embodiment

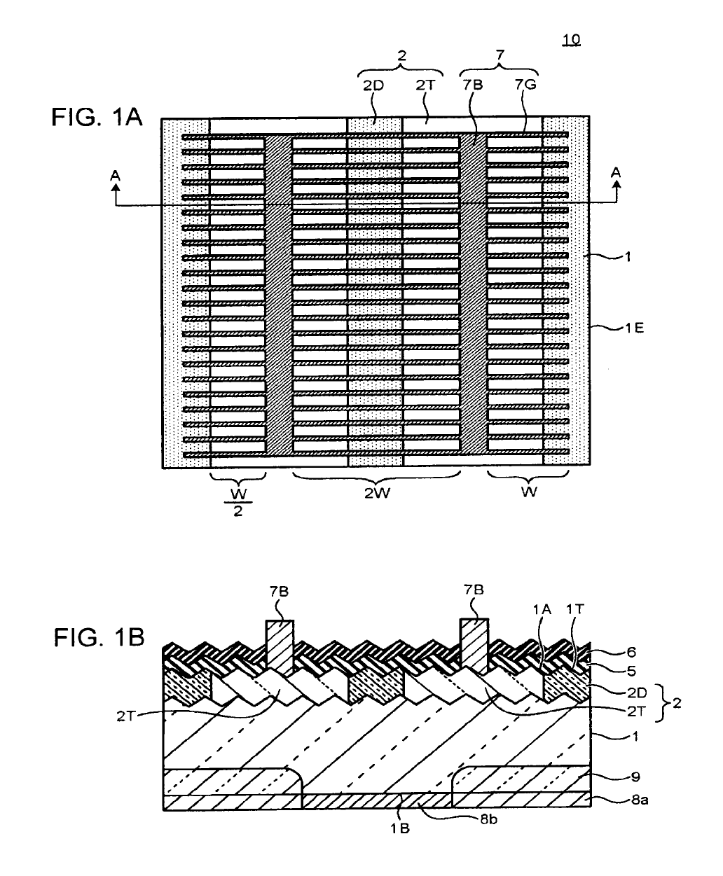

A first embodiment is a diffusion-type solar cell as an example of a crystalline solar cell. FIG. 1 is a diagram schematically illustrating the solar cell according to the first embodiment, where FIG. 1A is a plan view and FIG. 1B is a sectional view taken along line A-A in FIG. 1A. In a solar cell 10 according to the first embodiment, a first region 2T formed of a low-concentration n-type diffusion layer and a second region 2D formed of a high-concentration n-type diffusion layer are formed as second-conductivity-type diffusion regions, in a region surrounding bus electrodes 7B of a p-type monocrystalline silicon substrate 1, which is a first-conductivity-type semiconductor substrate. The first-conductivity-type semiconductor substrate has a first principal surface, which is a light receiving surface 1A, and a second principal surface, which is a back surface 1B. A p-type diffusion layer is formed if needed on the back surface 1B side. Further, a light-receiving surface electrode is formed on the light-receiving surface 1A. The light-receiving surface electrode is a first collector electrode 7 including the bus electrodes 7B and grid electrodes 7G. Meanwhile, a back surface electrode, which is a second collector electrode, is formed on the back surface 1B side. A silicon oxide (SiO₂) film 5, which is a passivation film, and a silicon nitride (SiN) film 6, which is an anti-reflective film, are stacked and formed on the light receiving surface 1A.

The solar cell 10 according to the present embodiment includes, on the light receiving surface 1A, the bus electrodes 7B and the comb-shaped grid electrodes 7G electrically connected to the bus electrodes 7B. If it is assumed that the length of the grid electrodes 7G with only one side being connected to the bus electrode 7B is W, the length of the grid electrodes 7G with both sides being connected to the bus electrode 7B is 2 W that is twice the length W. The boundary between the first region 2T having a low impurity concentration and the second region 2D having a high impurity concentration is set at a position where the distance from the bus electrodes 7B is W/2.

The bus electrodes 7B and the grid electrodes 7G are formed by screen printing using a conductive paste containing silver particles, which are conductive particles.

On the light receiving surface 1A side of the p-type monocrystalline silicon substrate 1, a microasperity 1T constituting a texture structure for confining light in the substrate is formed with a depth of about 5 micrometers. An n-type diffusion layer 2 is formed in the surface layer of the light receiving surface 1A of the p-type monocrystalline silicon substrate 1, i.e., in the surface layer of the microasperity 1T, thereby forming a p-n junction. That is, in the surface layer of the microasperity 1T, a low-concentration n-type diffusion layer having a sheet resistance of 90Ω/□ is formed by diffusion of n-type impurities, to constitute the first region 2T. Further, on the light receiving surface 1A side of the p-type monocrystalline silicon substrate 1, a low-resistance n-type diffusion layer can be formed immediately below the grid electrodes 7G in order to reduce the electrical contact resistance of the grid electrodes 7G, thereby constituting the second region 2D. The silicon oxide film 5, which is a passivation film, and the silicon nitride film 6, which is an anti-reflective film that reduces reflection of incident light to improve the light use efficiency, are formed on the surface of the light receiving surface 1A of the solar cell 10 excluding the grid electrodes 7G and the bus electrodes 7B, such as on the first region 2T, which is the high-resistance n-type diffusion layer.

An aluminum electrode 8a containing aluminum and a back-surface silver electrode 8b, which is an external lead-out electrode containing silver, are formed as the second collector electrode on the back surface side, on the back surface 1B of the p-type monocrystalline silicon substrate 1. On the back surface of the p-type monocrystalline silicon substrate 1, an alloy layer of aluminum and silicon is formed in the lower region of the aluminum electrode 8a, and a BSF (Back Surface Field) layer 9, which is a p⁺ layer provided by diffusion of aluminum, is formed below the alloy layer.

The p-type monocrystalline silicon substrate 1 used for the solar cell of the present embodiment has a substrate size of 156 millimeters long, 156 millimeters wide, and 180 micrometers thick, and two bus electrodes 7B are provided parallel to each other with an interval of 77 millimeters.

The grid electrodes 7G are provided at intervals of 2 millimeters such that they are orthogonal to the bus electrodes 7B, and the distance between the ends of the grid electrodes 7G and an end 1E of the p-type monocrystalline silicon substrate 1 is 2 millimeters.

The first region 2T, which is the low-concentration n-type diffusion layer 2, and the second region 2D, which is the high-concentration n-type diffusion layer 2, are formed by an ion implantation method by implanting PH₃ molecules. In this case, the dose amount in the high resistance region is set to a lower value than that in the low resistance region. The low-concentration n-type diffusion layer becomes the high resistance region and the high-concentration n-type diffusion layer becomes the low resistance region. It is assumed that the surface impurity concentration in the first region 2T is 1×10²⁰ cm⁻³ and the surface impurity concentration in the second region 2D is 2×10²⁰ cm⁻³.

In the solar cell 10 according to the present embodiment, the output characteristics can be improved by setting a region on the side away from the bus electrodes 7B as the second region 2D having a high impurity concentration and setting the first region 2T on the side close to the bus electrodes 7B as the region having a low impurity concentration.

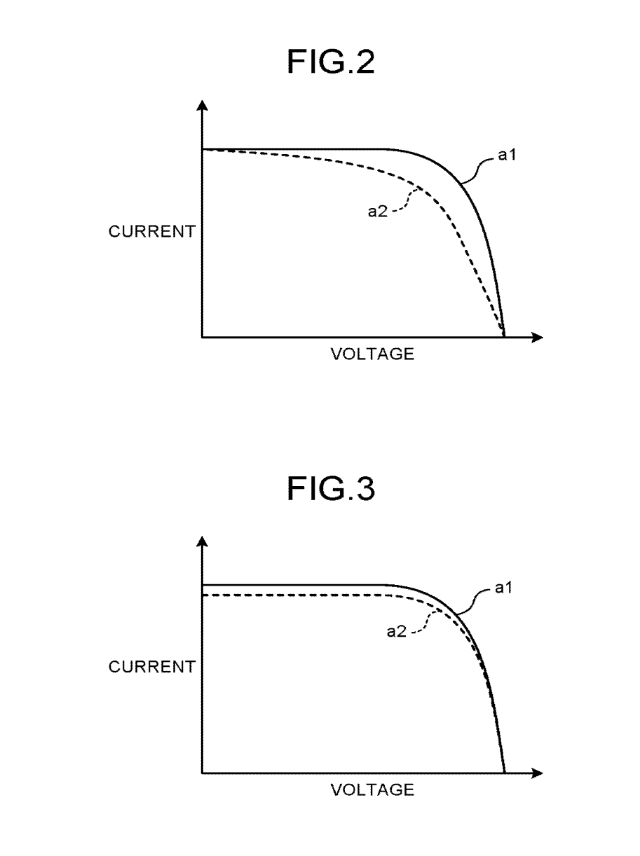

The reason thereof is considered as described below. The results of measurements of current-voltage characteristics in the first region 2T and the second region 2D when the respective regions have the same impurity concentration are illustrated in FIG. 2 respectively by curves a1 and a2. In the first region 2T, the distance through which photogenerated carriers pass in the grid electrodes 7G is short and the voltage drop caused by the grid electrodes 7G is small. Accordingly, the first region 2T exhibits the current-voltage characteristics with a high fill factor as illustrated by the curve a1. This case is defined as Example 1. Meanwhile, in the current-voltage curve a2 of the second region 2D, the distance through which the carriers collected in the grid electrodes 7G pass in the grid electrodes 7G is long and the voltage drop caused by the grid electrodes 7G is large. Accordingly, the maximum output in the current-voltage curve decreases. Because the entire output characteristics are obtained by combining these two current-voltage characteristics, the entire maximum-output operating voltage becomes different from the maximum-output operating voltages in the respective regions. Accordingly, the maximum output in the entire solar cell is lower than the sum of the maximum output values in the respective regions. Therefore, ideally, it is preferable that the voltage drop caused by parasitic resistance components is equal at all the points on the cell. To achieve this configuration, such a multilevel impurity region is preferable that the impurity concentration increases and the sheet resistance decreases in a location with distance passed along the grid electrodes 7G. More ideally, it is preferable to form the impurity region such that a location with a longer distance passed along the grid electrodes 7G has, in a continuous manner, a higher impurity concentration and a lower sheet resistance.

On the other hand, the results of measurements of the current-voltage characteristics when the first region 2T is set as the low-concentration impurity diffusion region and the second region 2D is set as the high-concentration impurity diffusion region are illustrated in FIG. 3 by curves a1 and a2. In this case, as illustrated in FIG. 3, the difference in the voltage drop between the first region 2T and the second region 2D decreases. Therefore, as compared to the graph illustrated in FIG. 2, the current-voltage curves a1 and a2 in the two regions have a similar shape to each other, and the maximum output operating voltages in the two regions indicate voltage values close to each other as compared to the graph illustrated in FIG. 2. Therefore, the entire maximum output has a value close to the sum of the maximum outputs of the first region 2T and the second region 2D, thereby leading to an increase of the maximum output in the entire solar cell.

It is preferable that the value acquired by dividing the difference in the sheet resistance between the first region 2T and the second region 2D by a grid interval (unit: millimeter (mm)) is equal to or larger than 20Ω/□×mm on the basis of the experimental results in Examples described later. Consequently, the in-plane distribution of the voltage drop can be reduced and thus the fill factor and the maximum output are improved. Further, the difference in sheet resistance between the first region 2T and the second region 2D is preferably equal to or larger than 40Ω/□. Accordingly, an effect of reducing the in-plane distribution of the voltage drop increases, thereby increasing the improvement rate of the fill factor and the maximum output.

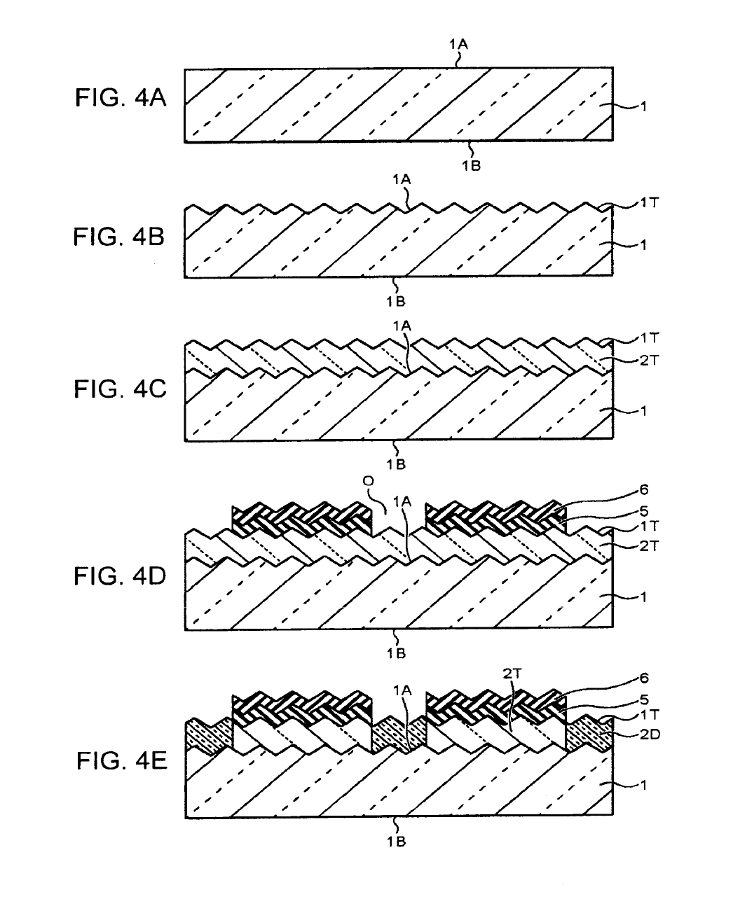

FIGS. 4A to 4E are manufacturing process diagrams of the solar cell according to the present embodiment. In the present embodiment, the n-type diffusion layer 2, which is the second-conductivity-type diffusion region, is formed on the p-type monocrystalline silicon substrate, which is a first-conductivity-type silicon substrate. A passivation film formed of a stacked film of the silicon oxide film 5 and the silicon nitride film 6 is formed on the silicon substrate formed with a p-n junction. An open region O is formed in the silicon oxide film 5 and the silicon nitride film 6, which are the passivation film on the light receiving surface 1A side. Further, n-type impurities are diffused with respect to the open region O by using the passivation film as a mask, to form the second region 2D, which is a high-concentration diffusion layer. The n-type diffusion layer other than the second region 2D, which is the high-concentration diffusion layer, is the first region 2T having a low concentration. The first collector electrode 7 is formed in alignment with the open region O of the passivation film, and the second collector electrode is formed on the back surface 1B side.

First, as illustrated in FIG. 4A, it is preferable to use the p-type monocrystalline silicon substrate 1 in which, for example, slice damage caused by slicing a silicon ingot is removed. Slice damage can be removed by etching, for example, with mixed acid of an aqueous hydrogen fluoride (HF) and nitric acid (HNO₃) or with an alkaline aqueous solution such as NaOH.

Next, as illustrated in FIG. 4B, a texture structure formed with the microasperity 1T is formed on the light receiving surface 1A of the p-type monocrystalline silicon substrate 1. A wet etching process is then performed by immersing the p-type monocrystalline silicon substrate 1 in an etching tank. After performing the wet etching process, the microasperity 1T formed of micro pyramids, each having a height from 8 micrometers to 21 micrometers and a bottom length from 1 micrometer to 30 micrometers, is randomly formed on the surface of the p-type monocrystalline silicon substrate 1. The micro pyramid is a triangular pyramid formed by using a silicon (111) surface as a principal surface.

The etching solution used for the wet etching process is acquired by adding an alcohol additive, such as isopropyl alcohol, a surfactant agent, or a silicate compound, such as sodium orthosilicate, to a solution in which a strong alkaline reagent, such as sodium hydroxide, potassium hydroxide, or tetramethylammonium hydroxide, is dissolved. The etching temperature is preferably from 40° C. to 100° C. and the etching time is preferably from 10 minutes to 60 minutes.

Next, the following first process and second process are performed in order to clean the surface of the p-type monocrystalline silicon substrate 1. In the first process, the p-type monocrystalline silicon substrate 1 is immersed in a cleaning solution containing concentrated sulfuric acid and a hydrogen peroxide solution to remove an organic substance on the surface of the p-type monocrystalline silicon substrate 1, and an oxide film on the p-type monocrystalline silicon substrate 1 formed at this point is then removed by a hydrofluoric acid solution. In the second process, the p-type monocrystalline silicon substrate 1 is immersed in a cleaning solution containing hydrochloric acid and a hydrogen peroxide solution to remove metallic impurities, and an oxide film on the p-type monocrystalline silicon substrate 1 formed at this point is removed by the hydrofluoric acid solution. The first process and the second process are repeatedly performed until organic contamination, metallic contamination, and contamination due to particles on the surface of the p-type monocrystalline silicon substrate 1 are sufficiently reduced. Cleaning can be also performed by functional water, such as cleaning by ozone water or cleaning by carbonated water.

Subsequently, as illustrated in FIG. 4C, phosphorus ions are implanted by the ion implantation method on the light receiving surface 1A side of the p-type monocrystalline silicon substrate 1 to form the n-type diffusion layer, which becomes the first region 2T. The surface impurity concentration of the n-type diffusion layer is set to 2×10²⁰ cm⁻³.

Next, as illustrated in FIG. 4D, the silicon oxide film 5 and the silicon nitride film 6 are formed on the light receiving surface 1A side of the p-type monocrystalline silicon substrate 1 and the open region O is formed. Both the silicon oxide film 5 and the silicon nitride film 6 have a function as the passivation film formed of a stacked film.

The processes described above are performed in the following manner. The silicon oxide film 5 is first formed as the passivation film on the surface of the p-type monocrystalline silicon substrate 1. When the silicon oxide film 5 is formed, cleaning before film formation is first performed on the surface of the p-type monocrystalline silicon substrate 1. As the cleaning before film formation, the following first process and second process are performed in a similar manner to the process after wet etching. In the first process, the organic substance on the surface of the p-type monocrystalline silicon substrate 1 is removed by the cleaning solution containing concentrated sulfuric acid and the hydrogen peroxide solution, and the oxide film formed at this point is then removed by the HF. In the second process, metallic impurities are removed by the cleaning solution containing hydrochloric acid and the hydrogen peroxide solution, and the oxide film on the p-type monocrystalline silicon substrate 1 formed at this point is removed by a hydrofluoric acid solution. The first process and the second process are repeatedly performed until organic contamination, metallic contamination, and contamination due to particles on the surface of the p-type monocrystalline silicon substrate 1 are sufficiently reduced. Cleaning can be also performed by functional water, such as cleaning by ozone water or cleaning by carbonated water. The silicon oxide film 5 is then formed on the light receiving surface 1A of the p-type monocrystalline silicon substrate 1 by dry oxidation. The dry oxidation is performed by using a high-temperature electric furnace. High-purity oxygen is delivered onto the p-type monocrystalline silicon substrate 1 to form the silicon oxide film 5. The film formation temperature is preferably from 900° C. to 1200° C. The film formation time is preferably from 15 minutes to 60 minutes. The silicon oxide film 5 is formed with a thickness in a range from 10 nanometers to 40 nanometers. The silicon oxide film 5 functions as the passivation film on the surface of the p-type monocrystalline silicon substrate 1. When the p-type monocrystalline silicon substrate 1 is formed, an aluminum oxide (Al₂O₃), a microcrystalline silicon film, an amorphous silicon thin film, or the like can be used as the passivation film. Alternatively, a stacked film of respective thin films described above as the passivation film and a silicon oxide film can be used.

Subsequently, the silicon nitride film 6 is formed on the light receiving surface 1A side of the p-type monocrystalline silicon substrate 1. An audinary pressure chemical vapor deposition (APCVD) method is used for forming the silicon nitride film 6. Gas to be used for film formation is SiH₄, N₃, NH₃, or O₂. The film formation temperature is equal to or higher than 300° C. The thickness of the silicon nitride film 6 is approximately from 10 nanometers to 200 nanometers. The silicon nitride film 6 can be used as an anti-reflective film in addition to a high passivation effect on the light receiving surface 1A.

Next, the stacked film of the silicon oxide film 5 and the silicon nitride film 6 formed as the passivation film on the p-type monocrystalline silicon substrate 1 is then etched into a given pattern. As the etching method, an etching paste is first screen-printed in a given pattern. In this case, a mask to be used for screen printing of the etching paste has a comb shape.

As the etching paste, one containing an etching component capable of etching the stacked film described above, and components other than the etching component, such as water, an organic solvent, and a thickening agent, can be used. At least one type selected from phosphoric acid, hydrogen fluoride, ammonium fluoride, and ammonium hydrogen fluoride is used as the etching component.

After the etching paste is printed, the stacked film of the silicon oxide film 5 and the silicon nitride film 6 is fired at a temperature equal to or higher than 100° C. for 1 minute or more to perform etching of the stacked film. The firing temperature or the firing time for etching is changed according to the composition of the etching component in the etching paste and the film composition of the stacked film of the silicon oxide film 5 and the silicon nitride film 6. When the stacked film of the silicon oxide film 5 and the silicon nitride film 6 is etched by using the etching paste, as illustrated in FIG. 4(d), the open region O is formed.

As a method of etching the stacked film of the silicon oxide film 5 and the silicon nitride film 6, other than the method of using the etching paste, photolithography or laser can be used.

After printing of the etching paste, ultrasonic cleaning by an ultrasonic bath is performed by using pure water or a sodium hydroxide solution having a low concentration of 1.0% or lower, to remove a residue of the etching paste. A cleaning solution containing concentrated sulfuric acid and a hydrogen peroxide solution, a hydrofluoric acid, or functional water such as ozone water can be used.

Next, as illustrated in FIG. 4E, high-concentration phosphorus ion implantation is performed on the open region O by the ion implantation method, to diffuse phosphorus, and a high-concentration n-type diffusion layer is formed as a high-concentration diffusion region, thereby forming the low-resistance second region 2D. The surface impurity concentration in the second region 2D is set to 2×10²⁰ cm⁻³.

Subsequently, the first collector electrode 7 and the second collector electrode are respectively formed on both sides of the p-type monocrystalline silicon substrate 1. The second collector electrode is first formed on the back surface 1B side, which is the second principal surface. A conductive paste made of silver and aluminum is applied by screen printing. Thereafter, the p-type monocrystalline silicon substrate 1 is fired at a temperature as high as 600° C. or above to acquire the second collector electrode. At this point, the aluminum electrode 8a containing aluminum and the back-surface silver electrode 8b, which is the external lead-out electrode containing silver, are formed as the second collector electrode on the back surface 1B of the p-type monocrystalline silicon substrate 1. An aluminum-silicon alloy layer is then formed in the lower region of the aluminum electrode 8a and the BSF layer 9 formed of a p⁺ layer is formed by aluminum diffusion below thereof.

At this point, even if an oxide film is formed on the surface, high-temperature firing can fire-through the oxide film to form an excellent junction. If the passivation film or the anti-reflective film is also formed on the back surface, a junction can be formed by firing-through the stacked film of the silicon oxide film and the silicon nitride film formed on the back surface.

A metal electrode is then formed on the light receiving surface 1A side of the p-type monocrystalline silicon substrate 1 and joined to the n-type diffusion layer 2. A conductive paste containing Ag is applied by screen printing to form the grid electrodes 7G and the bus electrodes 7B. The grid electrodes 7G and the bus electrodes 7B are positioned and formed such that an electrode pattern is arranged corresponding to the region in which concentration is divided in advance into the first region 2T and the second region 2D.

Firing is performed to reduce the contact resistance between the n-type diffusion layer 2, and the grid electrodes 7G and the bus electrodes 7B. In this embodiment, firing is performed at a temperature of about 200° C. in a firing furnace, although the temperature depends on the characteristics of the conductive paste.

The diffusion-type solar cell illustrated in FIGS. 1A and 1B are manufactured in the manner described above.

The region immediately below the grid electrodes 7G is not particularly defined as the second region 2D formed of the high-concentration n-type diffusion layer, and the region belonging to the first region 2T has a low concentration. That is, the region immediately below the grid electrodes 7G in a portion as the first region is defined as the low-concentration first region 2T around the grid electrodes 7G, and a boundary is formed according to the region dividing pattern. In this case, around the grid electrodes 7G close to the region intersecting with the bus electrodes 7B, there are many carriers moving through not only the n-type diffusion layer but also a low-resistance electrode layer, thereby maintaining the excellent current-voltage characteristics.

The first region 2T, which is a high-resistance region, and the second region 2D, which is a low-resistance region, can be formed by solid phase diffusion using a dopant paste containing dopant atoms such as phosphorus atoms. In this case, printing is performed simultaneously in the selective region immediately below the grid electrodes 7G, the second region 2D, and the first region 2T by using dopant pastes having different concentrations, thereby enabling suppression of an increase in the number of processes and enabling further improvement of the conversion efficiency. Formation of the second region 2D having a concentration distribution in a stepwise manner, in which concentration becomes higher moving closer to the substrate end, can be facilitated by using simultaneous printing.

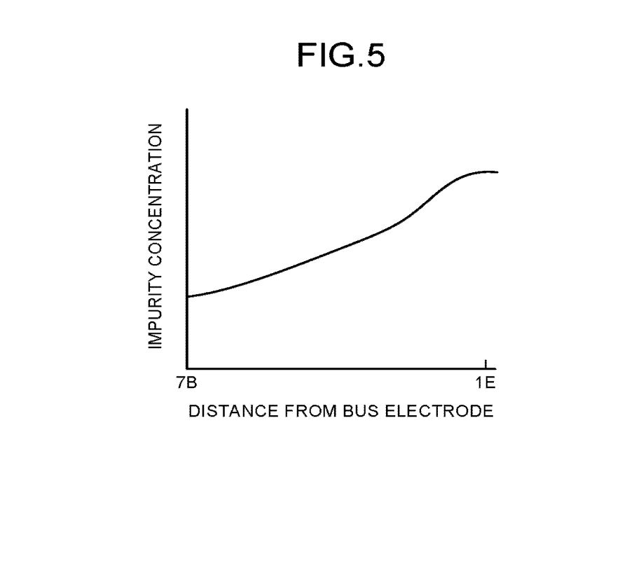

The second region 2D, which is the high-concentration impurity region, does not necessarily have a concentration distribution in a stepwise manner as described above and can have an inclined concentration distribution such that the impurity concentration becomes gradually higher with distance from the bus electrodes 7B, as illustrated in FIG. 5 as an impurity concentration distribution from a point under the bus electrodes 7B to the end 1E of the substrate. The voltage drop distribution in the cell surface of the solar cell further decreases by optimizing the current-voltage characteristics by using the inclined concentration distribution. Consequently, the fill factor and the maximum output of the solar cell can be further increased.

If the ends of the grid electrodes 7G and the substrate end of the solar cell are away from each other, for example, if the distance between the ends of the grid electrodes 7G and the substrate end of the solar cell is longer than the interval between the grid electrodes 7G adjacent to each other, it is desirable that the resistance is low between the end 1E and the ends of the grid electrodes 7G. That is, an effect of improving the output characteristics can be acquired by setting the boundary between the low-resistance region of the second region 2D and the high-resistance region of the first region 2T to the inner side of the region from the end 1E to the ends of the grid electrodes 7G. This is because carriers generated in the region from the end 1E of the p-type monocrystalline silicon substrate 1 to the ends of the grid electrodes 7G are likely to be affected by the resistance to lateral movement, and thus the mobility of the carriers can be increased by setting the region from the cell end to the ends of the grid electrodes 7G to have a low resistance. Further, if the ends of the grid electrodes 7G and the substrate end of the solar cell are away from each other, for example, if the distance between the ends of the grid electrodes 7G and the substrate end of the solar cell is longer than the interval between the grid electrodes 7G adjacent to each other, the high-concentration second region 2D can be formed only in a region from the substrate end to the ends of the grid electrodes 7G, excluding a region between the bus electrodes 7B in FIG. 1A.

According to the solar cell of the present embodiment, the light receiving surface is configured from an impurity region formed of two types of diffusion layers having different impurity concentrations. The region close to the bus electrodes is formed of a low-concentration impurity region and the region away from the bus electrodes is formed of a high-concentration impurity region. A photocurrent generated in a photoelectric conversion layer is collected by the grid electrodes. In this case, the light receiving surface is configured from the two types of impurity regions described above having different concentrations. The portion close to the bus electrodes is the low-concentration impurity region and has a large voltage drop per unit length. The portion away from the bus electrodes is the high-concentration impurity region and has a small voltage drop. Accordingly, an in-plane voltage drop can be made substantially constant, thereby enabling the output characteristics to be improved.

As described above, according to the solar cell of the present embodiment, the in-plane distribution of the voltage drop in the solar cell is reduced, the fill factor in the entire cell is improved, and thus the output characteristics are improved.

Furthermore, when grid electrodes are formed by a screen-printing method, the output variations of the solar cell caused by misalignment between the printing pattern and the semiconductor substrate can be suppressed. Because the horizontal conductivity is low around the grid electrodes away from the bus electrodes, power can be collected with a low resistance, thereby enabling the collector resistance to be suppressed.

In the solar cell according to the present embodiment, although the impurity concentration of the n-type diffusion layer 2 in the region immediately below the grid electrodes 7G is not particularly increased, the impurity concentration of the n-type diffusion layer 2 in the region immediately below the grid electrodes 7G can be selectively increased. For example, by forming the second region 2D formed of the high-concentration n-type diffusion layer immediately below the grid electrodes 7G, the current collecting performance of the grid electrodes 7G can be improved, thereby enabling further improvement of the fill factor.

As in a second embodiment described later, the boundary between a diffusion layer region having a high impurity concentration and a diffusion layer region having a low impurity concentration can have a longer distance from the gird electrodes with distance from the bus electrodes. Accordingly, an increase of the fill factor can be made larger.

The solar cell according to the first embodiment uses the p-type monocrystalline silicon substrate 1 as a semiconductor substrate. The semiconductor substrate is not limited thereto, and an n-type silicon substrate can be used or a polycrystalline silicon substrate can be used.

For example, it is also possible to form second-conductivity-type semiconductor layers having different impurity concentrations by a heterojunction solar cell. The second-conductivity-type semiconductor layers can be also realized by a method of increasing the concentration by performing additional diffusion into a portion constituting the second region. Further, the high-concentration impurity region can be selectively formed by using a mask.

### Second Embodiment

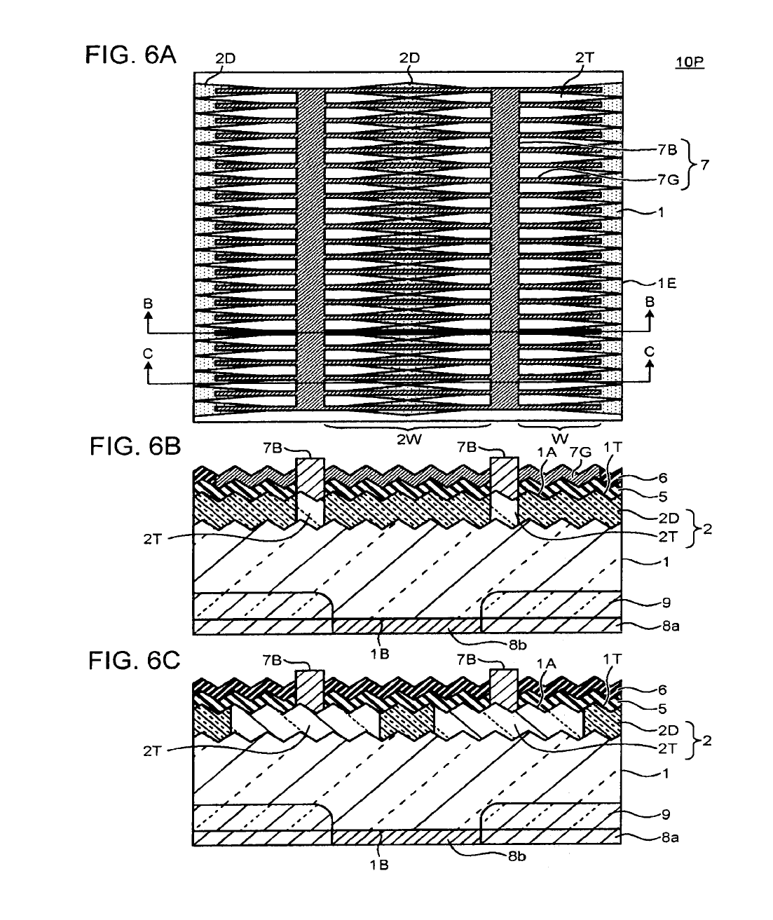

FIGS. 6A to 6C are diagrams schematically illustrating a solar cell according to the second embodiment, where FIG. 6A is a plan view, FIG. 6B is a sectional view taken along line B-B in FIG. 6A, and FIG. 6C is a sectional view taken along line C-C in FIG. 6A. Similarly to the solar cell of the first embodiment, in the solar cell according to the present embodiment, two n-type diffusion layers having different impurity concentrations are arranged on the p-type monocrystalline silicon substrate 1, as the low-concentration first region 2T and the high-concentration second region 2D. The cell configuration of a solar cell lop is similar to that of the first embodiment except for a planar arrangement of the first region 2T and the second region 2D, which are the n-type diffusion layers. In the solar cell according to the present embodiment, the first region 2T and the second region 2D, which are the n-type diffusion layers having different impurity concentrations, are distributed in such a manner that the distance from the grid electrodes 7G becomes longer as the boundary between the first and second regions 2T and 2D gets further away from the bus electrodes 7B. By providing the first region 2T and the second region 2D formed of the n-type diffusion layers having different impurity concentrations in such an in-plane distribution, the output characteristics can be further improved.

In this case, the high-concentration impurity region is formed in a region close to the grid electrodes 7G. This is because photogenerated carriers collected in the grid electrodes 7G increase with closeness to the grid electrodes 7G, and thus by reducing a resistance value R, a resistive loss W_{Ross}=RI² can be reduced. In the equation, R denotes a resistance value and I denotes a current value.

The boundary between the first region 2T and the second region 2D, which are two n-type diffusion layers having different impurity concentrations, can be linear or an arbitrary curve, such as a quadratic curve or an exponential curve. The boundary can have a shape effective to the output characteristics, respectively, according to the sheet resistance value of the two different impurity regions and the linear resistance value of the grid electrodes 7G.

When there is a boundary of the impurity regions, respectively, in the grid electrodes 7 adjacent to each other in parallel, the boundary points thereof can intersect at a point somewhere away from the bus electrodes 7B.

Also in the present embodiment, the high-concentration impurity region can have a concentration distribution such that the impurity concentration becomes higher with distance from the bus electrodes 7B. Further, the high-concentration impurity region can be formed by the ion implantation method or a solid-phase diffusion method by impurity diffusion from dopant pastes having different concentrations.

### Third Embodiment

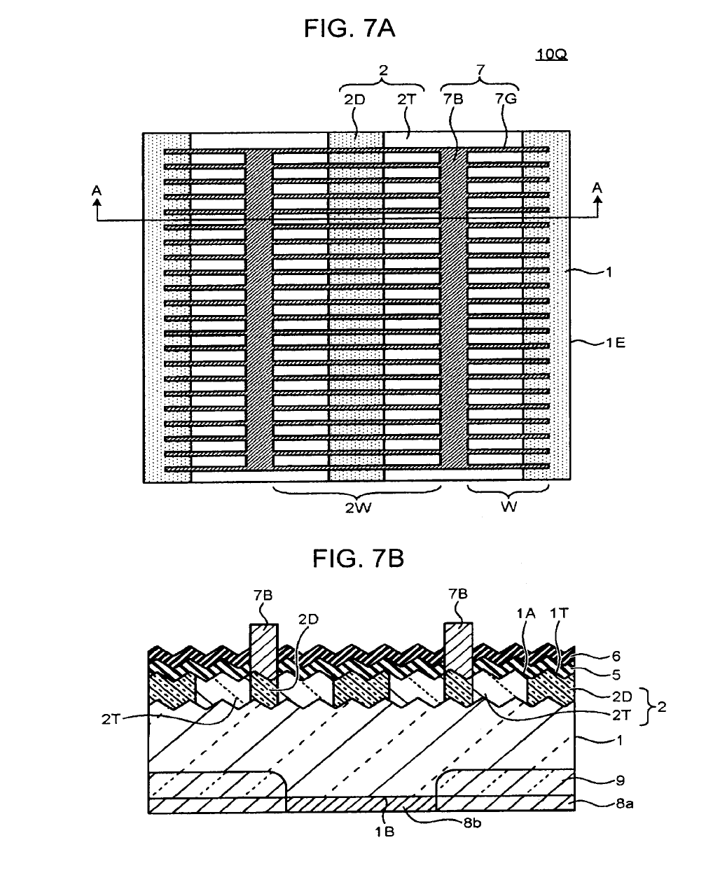

FIGS. 7A and 7B are diagrams schematically illustrating a solar cell according to a third embodiment, where FIG. 7A is a plan view and FIG. 7B is a sectional view taken along line A-A in FIG. 7A. A solar cell 10Q according to the present embodiment is different from the solar cell of the first embodiment only in that the region immediately below the bus electrodes 7B and the region immediately below the grid electrodes 7G are constituted by an n-type diffusion layer having a concentration same as that of the high-concentration second region 2D. Other elements of the present embodiment are similar to those of the solar cell of the first embodiment, and two n-type diffusion layers having different impurity concentrations are arranged on the p-type monocrystalline silicon substrate 1, as the low-concentration first region 2T and the high-concentration second region 2D.

In the present embodiment, the contact resistance against the n-type diffusion layer 2 in the bus electrodes 7B and the grid electrodes 7G is reduced, thereby enabling the current-voltage characteristics to be improved as compared with the solar cell according to the first embodiment. The output characteristics can be further improved by providing the first region 2T and the second region 2D, formed of the n-type diffusion layer 2 having different impurity concentrations in such an in-plane distribution. However, it is required to perform highly accurate positioning at the time of forming the bus electrodes 7B and the grid electrodes 7G so that the region immediately below the bus electrodes 7B and the region immediately below the grid electrodes 7G become the high-concentration second region 2D.

In the present embodiment, only the region immediately below the bus electrodes 7B can be the high-concentration region without separately setting the region immediately below the grid electrodes 7G as the high-concentration region. Manufacturing is facilitated by setting the n-type diffusion layer 2 immediately below the grid electrodes 7G or immediately below the bus electrodes 7B to have an impurity concentration same as that of the second region. However, in view of achieving a low resistance, the impurity concentration thereof does not need to be the same as that of the second region 2D, and it is sufficient that the n-type diffusion layer has a higher impurity concentration than that of the first region 2T.

Furthermore, in the present embodiment, a configuration in which a tab wire is directly connected to the cell constituting the solar cell is also possible, without separately providing a bus electrode. In particular, in the present embodiment, the contact resistance against the tab wire can be reduced by setting a region under the tab wire as a high-concentration region, thereby enabling a solar cell having high photoelectric conversion efficiency to be acquired.

In the first to third embodiments, in the second-conductivity-type impurity region, the impurity concentration of the first region 2T surrounding the bus electrodes 7B, which are the current-collecting portion, is set to be lower than that of the second region 2D, which is away from the bus electrodes 7B, which are the current-collecting portion, and the sheet resistance of the first collector-electrode forming surface is made low, so that the voltage drop caused by the parasitic resistance components becomes equal at all the points on the cell. In addition, not only the sheet resistance of the second-conductivity-type impurity region but also the impurity concentration of the semiconductor substrate itself can have a distribution so that the sheet resistance of the first collector-electrode forming surface has a distribution. Alternatively, the sheet resistance of a translucent conductive film can have a distribution. Even in the case where the impurity concentration of the semiconductor substrate itself has a distribution so that the sheet resistance of the first collector-electrode forming surface has a distribution, the sheet resistance can be high in the first region of the semiconductor substrate because the distance through which the photogenerated carriers pass in the grid electrodes 7G is short and the voltage drop caused by the grid electrodes 7G is small in the first region of the semiconductor substrate. Meanwhile, in the second region of the semiconductor substrate, because the distance through which the carriers collected in the grid electrodes 7G pass in the grid electrodes 7G is long and the voltage drop caused by the grid electrodes 7G is large, control is executed such that the sheet resistance is reduced to suppress the voltage drop. Because the entire output characteristics are obtained by combining the current-voltage characteristics in these two regions, it is ideally preferable to perform adjustment such that the voltage drop caused by the parasitic resistance components is equal at all the points on the cell. To achieve this configuration, a multilevel impurity region is preferable in which the sheet resistance of the semiconductor substrate decreases with distance through which electric charges generated in a location pass in the grid electrodes 7G. The case where the sheet resistance of the translucent conductive film has a distribution is described later in a fourth embodiment, and the case where the concentration of the semiconductor substrate has a distribution is described later in sixth and seventh embodiments.

### Fourth Embodiment

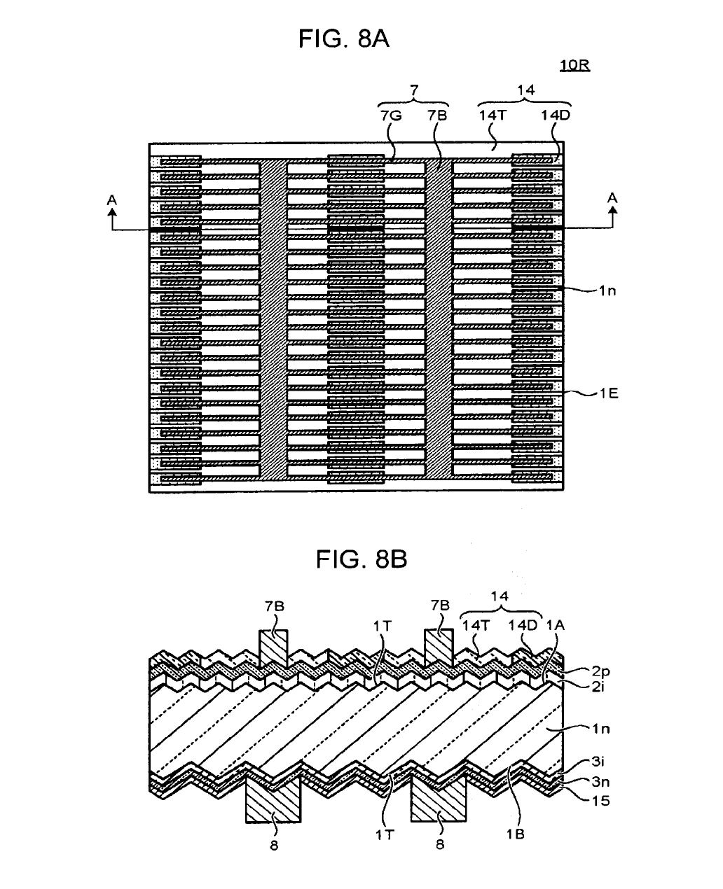

FIGS. 8A and 8B are diagrams schematically illustrating a solar cell according to the fourth embodiment, where FIG. 8A is a plan view and FIG. 8B is a sectional view taken along line A-A in FIG. 8A. The solar cell described in the first to third embodiments is a diffusion-type solar cell. However, the solar cell according to the present embodiment is a heterojunction solar cell. In the present embodiment, the impurity concentration of a conductive layer constituting a p-n junction is not changed, but the sheet resistance of a translucent conductive film to be formed on the conductive layer has an in-plane distribution. In the present embodiment, a translucent conductive film 14 has a sheet resistance distribution. The translucent conductive film 14 is formed on a p-type amorphous silicon layer 2p, which is a second-conductivity-type impurity region that forms a p-n junction with an n-type monocrystalline silicon substrate 1n, which is a first-conductivity-type semiconductor substrate. A first translucent conductive film 14T constituting a first translucent conductive region including the region under the bus electrodes 7B, of the translucent conductive film 14, has a sheet resistance higher than that of a second translucent conductive film 14D, which is away from the bus electrodes 7B and constitutes a second translucent conductive region including the peripheral edge portion of the n-type monocrystalline silicon substrate 1n. Although the layer configuration is described later, the solar cell is a general heterojunction solar cell except that the translucent conductive film 14 has a sheet resistance distribution.

The first and second translucent conductive films 14T and 14D are made of tin oxide having different tin concentrations and are formed sequentially by a sputtering method using targets having different tin concentrations.

In the present embodiment, as a first-conductivity-type semiconductor substrate, the n-type monocrystalline silicon substrate 1n is used. The n-type monocrystalline silicon substrate 1n includes a (100) plane as a surface. In a solar cell 10R according to the present embodiment, the microasperity 1T having a pyramid structure formed of a (111) plane is formed on the first principal surface constituting the light receiving surface 1A and the second principal surface constituting the back surface 1B.

The solar cell 10 according to the present embodiment includes the translucent conductive film 14 on the light receiving surface 1A side of the n-type monocrystalline silicon substrate 1n and a translucent conductive film 15 on the back surface 1B side thereof.

On the back surface 1B side, the solar cell 10R includes, on an amorphous silicon i layer 3i, which is a thin film layer, an n-type silicon layer 3n having an effect of collecting carriers by a BSF effect.

The solar cell 10R also includes the first collector electrode 7 for electrical connection to the translucent conductive film 14 on the light receiving surface 1A side and a second collector electrode 8 for electrical connection to the translucent conductive film 15 on the back surface 1B side. The first collector electrode 7 arranged on the light receiving surface 1A is configured from the grid electrodes 7G arranged parallel to each other at regular intervals and two bus electrodes 7B orthogonal to the grid electrodes 7G. The second collector electrode 8 is formed with two patterns that are in parallel with the bus electrodes 7B on the light receiving surface 1A.

The second translucent conductive film 14D having a low sheet resistance generally has a high carrier density and thus absorption of infrared light increases due to free carrier absorption. Accordingly, it is required to arrange the second translucent conductive film 14D having a low sheet resistance such that the in-plane arrangement thereof is as small as possible at an effective position.

Therefore, in the present embodiment, it is preferable that the second translucent conductive film 14D in the second translucent conductive region having a low sheet resistance is provided only at a portion close to the grid electrodes 7G and the width thereof is a quarter of the interval between the grid electrodes 7G parallel to each other. With this configuration, the fill factor can be improved while suppressing a decrease of a current value I of the photocurrent, and thus the output characteristics are improved.

With this configuration, the in-plane distribution of the voltage drop in the solar cell is further reduced, the entire fill factor is improved, and thus the output characteristics are improved.

The reason why the second translucent conductive film 14D in the second translucent conductive region having a low sheet resistance is provided in the region close to the grid electrodes 7G is described below. As described in the second embodiment, carriers generated in the region from the cell end to the ends of the grid electrodes 7G are likely to be affected by the resistance to lateral movement, and thus the mobility of the carriers can be increased by setting the region from the end 1E of the substrate to the ends of the grid electrodes 7G to have a low resistance.

That is, if the sheet resistance is reduced, the transmission factor may decrease. Therefore, adjustment of the in-plane arrangement needs to be performed while acquiring optimal values of the sheet resistance and the transmission factor. The photoelectric conversion efficiency can be increased by increasing the amount of light received and reducing the contact resistance in the manner described above.

The method of forming the translucent conductive film according to the present embodiment is not limited to a sputtering method, and an ion plating method or other vapor-deposition methods can also be used.

In this case, the first translucent conductive film 14T in the first translucent conductive region and the second translucent conductive film 14D in the second translucent conductive region, which are formed of two different types of translucent conductive films, can be formed by using masks of different patterns or masks of reversal patterns.

The translucent conductive films 14 and 15 can be formed by using inorganic films made of, for example, In₂O₃, ZnO, CdO, CdIn₂O₄, CdSnO₃, MgIn₂O₄, CdGa₂O₄, GaInO₃, InGaZnO₄, Cd₂Sb₂O₇, Cd₂GeO₄, CuAIO₂, CuGaO₂, SrCu₂O₂, TiO₂, and Al₂O₃, in addition to the tin oxide SnO₂, as the material thereof. Alternatively, a translucent conductive film formed by stacking these materials can be used. Further, an element of at least one kind selected from Al, Ga, In, B, Y, Si, Zr, Ti, F, and Ce can be used as a dopant. By changing the composition ratio or adjusting the amount of the dopant, the sheet resistance of the translucent conductive film can be adjusted.

The second translucent conductive film 14D in the second translucent conductive region having a low resistance can be formed only in a portion close to the grid electrodes 7G. In this case, the width thereof is preferably a quarter of the interval between the grid electrodes 7G parallel to each other. With this width, the fill factor can be improved while suppressing a decrease of the current value I of the photocurrent, and thus the output characteristics can be improved.

Also in the first to third embodiments described above, the pattern arrangement as illustrated in the plan view of FIG. 8A can be used, and the second region 2D, which is the diffusion layer portion having a high impurity concentration, can be formed only in the portion close to the grid electrodes 7G. In this case, the width thereof is preferably a quarter of the interval between the grid electrodes 7G parallel to each other. With this width, the fill factor can be improved while suppressing a decrease of the current value of the photocurrent, and thus the output characteristics can be improved.

In the solar cell according to the present embodiment, the light-receiving surface of the substrate is configured from the first and second translucent conductive regions formed of the translucent conductive films having different types of sheet resistances. The solar cell further includes the grid electrodes patterned in a comb shape by a printing method using a silver paste on the translucent conductive film and the bus electrodes electrically connecting the grid electrodes.

Furthermore, in the solar cell according to the present embodiment, it is also possible that two types of impurity diffusion layers having different concentrations are formed separately in the plane as the diffusion layer portion on the light-receiving surface, and a portion close to the bus electrodes is a translucent conductive film having a high sheet resistance while a portion away from the bus electrodes is a translucent conductive film having a low sheet resistance. With this configuration, higher efficiency can be achieved.

### Fifth Embodiment

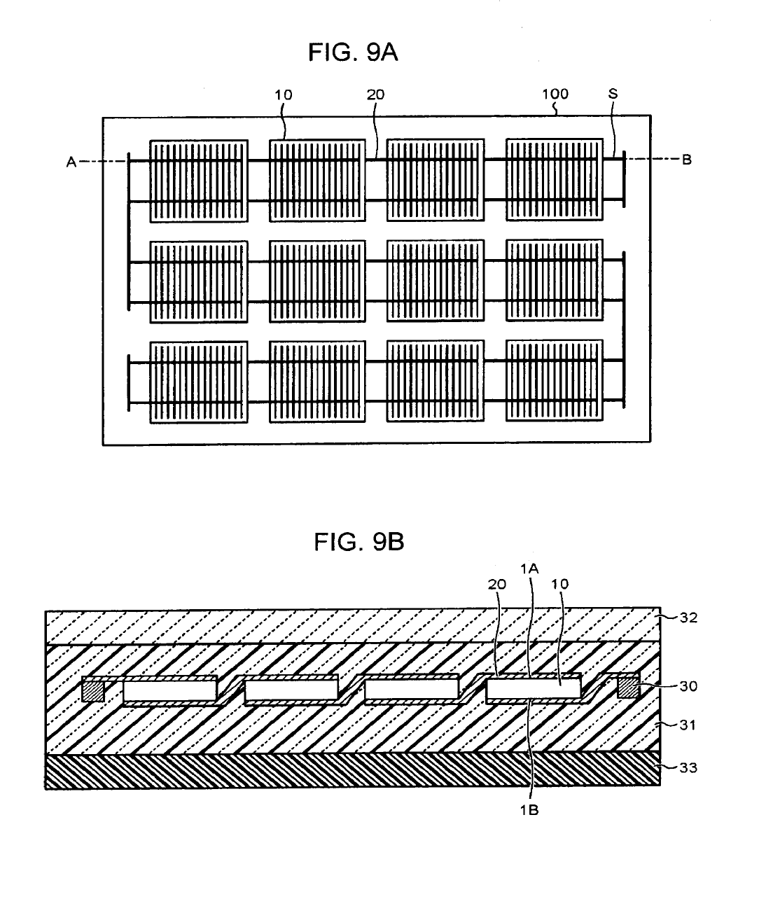

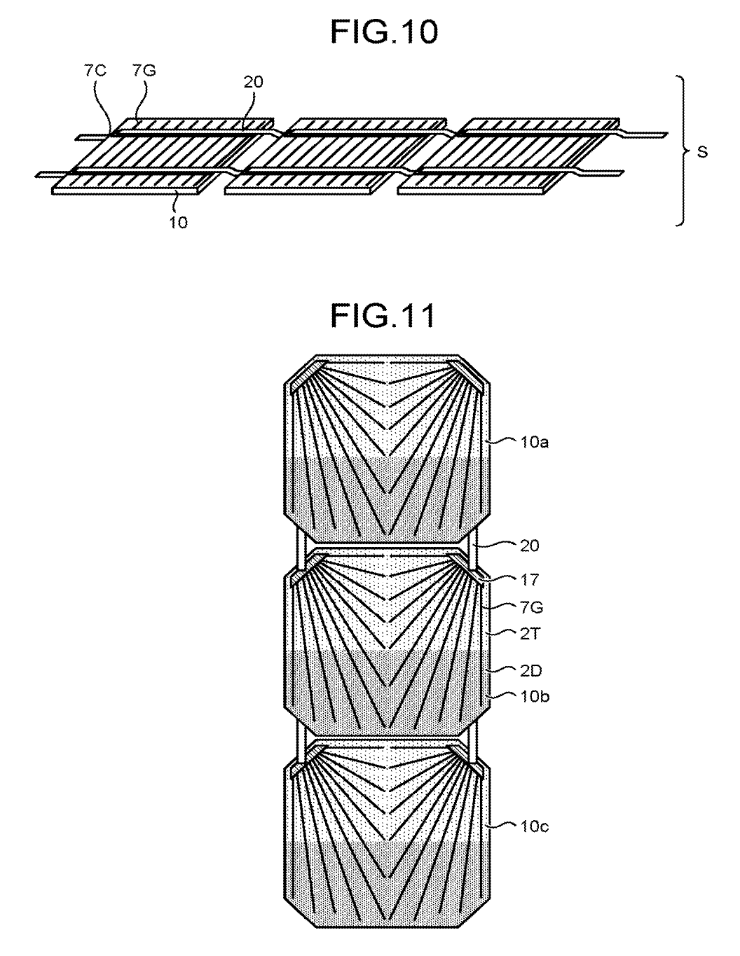

In the first to fourth embodiments described above, there has been described a solar cell in which the bus electrodes 7B and the grid electrodes 7G are formed as the first collector electrode 7 to be arranged on the light-receiving surface 1A. However, the present invention can be also applied to a configuration in which the bus electrodes are not separately provided, and tab wires 20 are directly connected to the cell constituting the solar cell 10. FIG. 9A is a top view schematically illustrating an example of a structure of a solar cell module 100 according to a fifth embodiment, which is viewed from the light-receiving surface 1A, which receives the sunlight. FIG. 9B is a sectional view illustrating the structure of the solar cell module 100 according to the fifth embodiment, which is a section taken along a dotted line between A and B in FIG. 9A. As illustrated in a perspective view in FIG. 10, in the fifth embodiment, one end of each of the tab wires 20 constituting inter-connectors is soldered onto a current-collecting portion 7C instead of the bus electrode 7B, without forming the bus electrodes 7B in the solar cell 10. The other end of each of the tab wires 20 is soldered to a second collector electrode (not illustrated) on the cell back surface of the adjacent solar cell to connect the solar cells in series, thereby forming a string S. The string S is sealed by a sealing resin 31 to constitute the solar cell module 100. Although not illustrated, similarly to the solar cell described in the first embodiment, a region on the side away from the current-collecting portions 7C, which are orthogonal to the grid electrodes 7G on the light-receiving surface 1A side, is set as the second region 2D having a high impurity concentration, and the first region 2T on the side close to the bus electrodes 7B is set as a region having a low impurity concentration.

Also in the present embodiment, similarly to the first embodiment, by increasing the impurity concentration in the region away from the current-collecting portions 7C so as to increase the mobility of carriers on the substrate surface, the in-plane distribution of the voltage drop can be reduced, thereby enabling the fill factor and the maximum output to be improved.

In the solar cell module 100, the solar cells 10 are connected to each other by the tab wires 20 and sealed by the sealing resin 31 between a glass plate 32, which is a protection member on the light-receiving surface side, and a back film 33, which is a protection member on the back surface side. Although not illustrated, the solar cell 10 includes first and second collector electrodes on the surface on the light-receiving surface 1A side and the surface on the back surface 1B side. The electrodes of the arrayed solar cells 10 adjacent to each other are connected in series by the tab wires 20 and are sealed in a state of forming the string S as illustrated in the perspective view of FIG. 10 and in the top view of FIG. 9A. Because of space limitations of the drawing, only three cells are illustrated in FIG. 10. The first collector electrode 7 on the light-receiving surface 1A side is formed of only the grid electrodes 7G, bus electrodes are not formed, and the current-collecting portions 7C on the surface of the solar cell are directly connected to the tab wires 20. Although not illustrated, the second collector electrode is also formed on the back surface 1B of the solar cell 10. The tab wires 20 are electrically connected to the current-collecting portions 7C on the light-receiving surface 1A and the second collector electrode on the back surface side of the adjacent cell. Reference sign 30 denotes a lead for leading out the tab wires to the outside.

As the glass plate 32, for example, a material, such as soda-lime glass, can be used. A film having low moisture permeability or a glass plate similar to that on the surface side is used as the back film so that the solar cell 10 is not deteriorated due to, for example, ingress of water. As the sealing resin 31, translucent EVA or a silicone resin can be used. As the tab wires 20 constituting the inter-connectors, for example, copper wires coated with solder can be used.

In the solar cell connected to the tab wires 20 constituting the inter-connectors, the high-concentration impurity region can be arranged in a portion away from the tab wires. With this arrangement, the voltage drop distribution due to the current drawing length in the solar cell is moderated, and similar effects to a case where the high-concentration impurity region is arranged in a portion away from the bus electrodes within the surface of the solar cell can be acquired.

FIG. 11 is a diagram schematically illustrating a string of solar cells that do not include bus electrodes and are used in a modification of the solar cell module according to the fifth embodiment. In this example, as illustrated in FIG. 11, first to third solar cells 10a to 10c constitute a densely connected string S in which a light shielding region that generates a shadow loss due to the tab wires 20 is small and a region between the cells is small. The tab wires 20 extend from the back surface of the solar cells, pass through the corner portions of the first solar cell 10a and the second solar cell 10b, and are soldered to the electrodes 9 for contact with the tab wires. In the solar cell module, the electrodes 17 for contact with the tab wires are provided at two corner portions of each solar cell, and the grid electrodes 7G are radially formed therefrom. Because the grid electrodes 7G become long, it is preferable to form the grid electrodes 7G by copper plating or the like having low resistivity.

In this example, the high-concentration impurity region is formed in a region away from the electrodes 9 for contact with the tab wires. This is because, in the portion away from the electrodes 9 for contact with the tab wires, a resistive loss increases and thus this portion is set as a high concentration region. By increasing the concentration of the photogenerated carriers collected in the grid electrodes 7G and reducing the resistance value R, the resistive loss W_{Ross}=RI² can be reduced. In the equation, R denotes a resistance value and I denotes a current value.

The boundary between the first region 2T and the second region 2D, which are two n-type diffusion layers having different impurity concentrations, can be linear or an arbitrary curve, such as a quadratic curve or an exponential curve. The boundary can have a shape effective to the output characteristics, respectively, according to the sheet resistance value of the two different impurity regions and the linear resistance value of the grid electrodes 7G.

### Sixth Embodiment

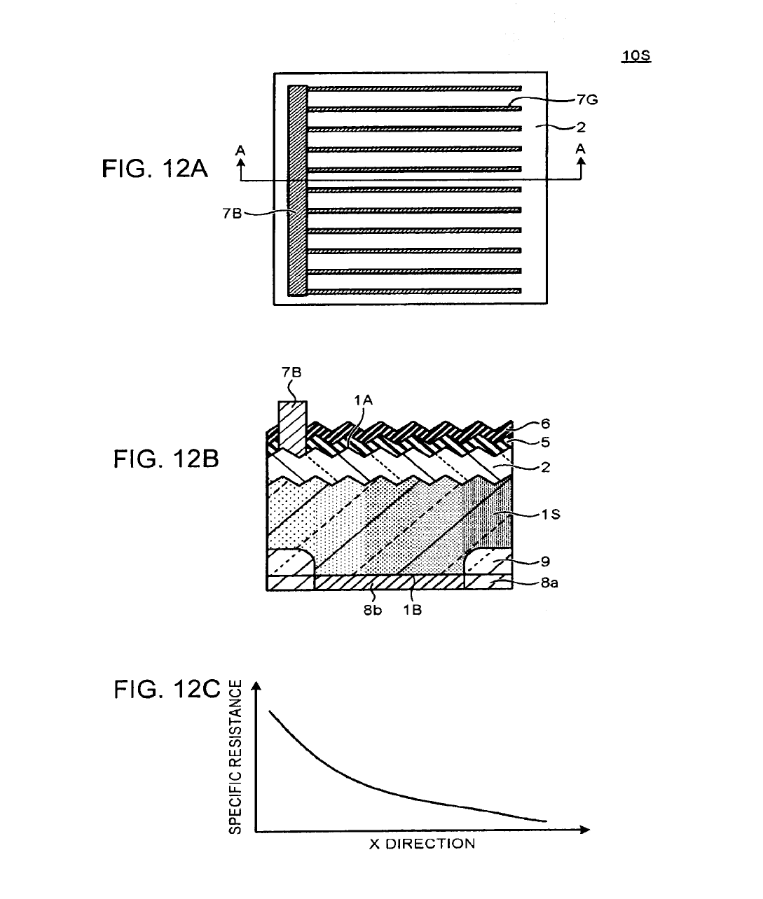

FIGS. 12A to 12C are diagrams schematically illustrating a solar cell according to a sixth embodiment, where FIG. 12A is a plan view, FIG. 12B is a sectional view taken along line A-A in FIG. 12A, and FIG. 12C is a diagram illustrating a specific resistance of a p-type monocrystalline silicon substrate 1S, which is a first-conductivity-type semiconductor substrate. In the solar cell according to the present embodiment, the impurity concentration of the n-type diffusion layer provided on the p-type monocrystalline silicon substrate 1S is uniform, which is different from the solar cell according to the first embodiment. The cell configuration of the solar cell according to the present embodiment is similar to that of the first embodiment except for the plane arrangement of the first region 2T and the second region 2D, which are the n-type diffusion layers, and the electrode arrangement on the light receiving surface side. In the solar cell according to the present embodiment, the bus electrode 7B is arranged along one side of the p-type monocrystalline silicon substrate 1, and the grid electrodes 7G extend from the bus electrode 7B toward the other side thereof. The impurity concentration has a distribution such that the impurity concentration of the p-type monocrystalline silicon substrate 1S increases with distance from the bus electrode 7B. The output characteristics can be further improved by selectively arranging the bus electrode 7B on the in-plane distribution of impurities of the p-type monocrystalline silicon substrate 1.

Other elements of the present embodiment are similar to those of the first embodiment. A solar cell 10S according to the sixth embodiment includes the first principal surface, which is to be the light receiving surface 1A, and the second principal surface, which is to be the back surface 1B. In the solar cell 10S, the n-type diffusion layer 2 having a constant impurity concentration is formed as a second-conductivity-type diffusion region on the light receiving surface 1A side of the p-type monocrystalline silicon substrate 1S, which is the first-conductivity-type semiconductor substrate having an impurity concentration distribution. A p-type diffusion layer is formed if needed on the back surface 1B side. Further, a light-receiving surface electrode is formed on the light-receiving surface 1A. The light-receiving surface electrode is the first collector electrode 7 including the bus electrode 7B and the grid electrodes 7G. Meanwhile, a back surface electrode, which is the second collector electrode 8, is formed on the back surface 1B side. Further, the silicon oxide (SiO₂) film 5, which is the passivation film, and the silicon nitride (SiN) film 6, which is the anti-reflective film, are stacked and formed on the light receiving surface 1A.

The impurity concentration may have a distribution between the central portion and the peripheral edge portion of the substrate in the case of a semiconductor substrate manufactured by the Czochralski method, such as the monocrystalline silicon substrate. Therefore, the created solar cells may not be in an appropriate resistor design as a result because the sheet resistance changes within the substrate surface. Therefore, according to the present embodiment, particularly, one silicon substrate is cut into a plurality of pieces in a square shape along cut lines including the center, and a substrate having a sheet resistance distribution between a certain side and the opposite side thereof in the cut substrate is used.

The semiconductor substrate to be used in the present embodiment can be easily formed by adjusting conditions, such as the temperature, the pulling speed, or the convection state of a melt, during a pulling process of an ingot and using a semiconductor substrate having an impurity concentration distribution. To have an impurity concentration distribution, impurity diffusion can be performed on the substrate surface. In this case, the impurity concentration can be changed in a stepwise manner. Further, a configuration in which the impurity concentration gradually changes with distance from the bus electrode 7B, for example, a distribution in which the boundary is illustrated in FIG. 6A can be used for the boundary between regions having different impurity concentrations, i.e., between the first region 2T and the second region 2D. Alternatively, as illustrated in FIG. 7A, the impurity concentration of the semiconductor substrate can have a distribution in two steps such that the boundary between the first region 2T and the second region 2D is formed in a portion at a certain distance from the bus electrode 7B. In other words, the impurity concentration distribution can be appropriately adjusted.

For the substrate to be used in the present embodiment, not only the monocrystalline silicon substrate but also a compound semiconductor substrate, such as a gallium arsenide substrate, can be used.

### Seventh Embodiment

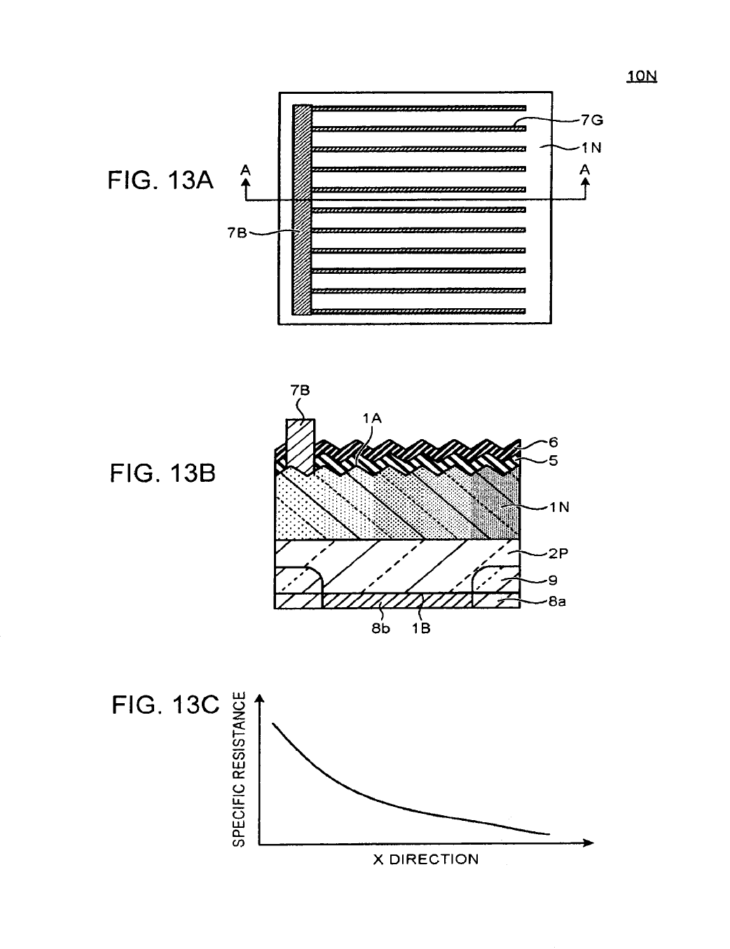

FIGS. 13A to 13C are diagrams schematically illustrating a solar cell according to a seventh embodiment, where FIG. 13A is a plan view, FIG. 13B is a sectional view taken along line A-A in FIG. 13A, and FIG. 13C is a diagram illustrating a specific resistance of an n-type monocrystalline silicon substrate 1N, which is the first-conductivity-type semiconductor substrate.

A solar cell 10N according to the seventh embodiment is a modification of the solar cell according to the sixth embodiment. As illustrated in FIGS. 13(a) to 13(c), the solar cell 10N has such a configuration in which the n-type monocrystalline silicon substrate 1N having an impurity concentration distribution is arranged on the light-receiving surface 1A side and a p-type diffusion layer 2P is arranged on the back surface side. The top view and the impurity concentration distribution of the semiconductor substrate are similar to those illustrated in FIG. 12A and FIG. 12C, and thus descriptions thereof are omitted.

With this configuration, an electrode configuration more efficiently reflects a drawing resistance distribution due to the concentration distribution in the n-type monocrystalline silicon substrate 1N. Accordingly, more efficient current-voltage characteristics can be acquired. It is obvious that the solar cell according to the present embodiment can be configured by using a p-type monocrystalline silicon substrate and forming an n-type diffusion layer.

### Example 1

Table 1 represents the measurement results of the solar cell characteristics of the solar cell manufactured on the basis of the first embodiment, as Example 1. In Example 1, the solar cell 10 illustrated in FIG. 1A and FIG. 1B was manufactured on the basis of the first embodiment.

TABLE 1

| SHEET | | | | |
|---|---|---|---|---|
| RESISTANCE | | | SHORT- | |
| OF LIGHT- | | | CIRCUIT | |
| RECEIVING | | | CURRENT | CONVERSION |
| SURFACE | OPEN VOLTAGE | FILL FACTOR | VALUE | EFFICIENCY |
| 50 Ω/□ | 0.639 | 0.795 | 39.5 | 20.06 |
| 70 Ω/□ | 0.640 | 0.792 | 39.7 | 20.12 |
| 90 Ω/□ | 0.640 | 0.789 | 39.9 | 20.15 |
| FIRST | 0.640 | 0.790 | 39.7 | 20.07 |
| REGION: 50 Ω/□ | | | | |
| SECOND | | | | |
| REGION: 90 Ω/□ | | | | |
| FIRST | 0.640 | 0.791 | 39.8 | 20.15 |
| REGION: 90 Ω/□ | | | | |
| SECOND | | | | |
| REGION: 70 Ω/□ | | | | |
| FIRST | 0.640 | 0.794 | 39.7 | 20.18 |
| REGION: 90 Ω/□ | | | | |
| SECOND | | | | |
| REGION: 50 Ω/□ | | | | |

Table 1 represents the measurement results of the open voltage, fill factor, short-circuit current value, and conversion efficiency in the solar cell in Example 1.

When the sheet resistance on the light-receiving surface of the n-type diffusion layer is uniform, lateral resistance components of the carriers decrease as the sheet resistance decreases, thereby increasing the fill factor. However, the short-circuit current value decreases due to an increase of Auger recombination in which electrons are knocked out at the time of electron-hole recombination that occurs because the impurity concentration is high.

In the case where the sheet resistance in the first region 2T is 50Ω/□ and the sheet resistance in the second region 2D is 90Ω/□, because the sheet resistance value in a region having a large voltage drop due to the grid electrodes 7G is large, the in-plane distribution of the voltage drop is amplified further than in the case where the in-plane sheet resistance value is uniform. Further, an increase of the fill factor is small and the short-circuit current value decreases as compared with the case where the in-plane sheet resistance value is uniform at 90Ω/□. Therefore, the conversion efficiency decreases as compared with the case where the in-plane sheet resistance value is uniform at 90Ω/□.

On the other hand, in the case where the sheet resistance in the first region 2T is 90Ω/□ and the sheet resistance in the second region 2D is 50Ω/□, the voltage drop due to the grid electrodes 7G in the second region 2D is compensated by setting the sheet resistance to be low. Therefore, the difference in the fill factor is as low as 1/1000 as compared with the case where the in-plane sheet resistance is uniform at 50Ω/□. The short-circuit current value was higher by 0.2 mA/cm² than the case where the in-plane sheet resistance is uniform at 50Ω/□, and thus the conversion efficiency took a value of 20.18%, which is higher than any case where the sheet resistance on the light-receiving surface is uniform.

Furthermore, the conversion efficiency in the case where the sheet resistance in the first region 2T is 90Ω/□ and the sheet resistance in the second region 2 is 70Ω/□ is 20.15%. Accordingly, it was found that effective output characteristics was able to be acquired when the difference in the sheet resistance value between the first region 2T and the second region 2D is large to some extent.

With this configuration, by setting the difference in the sheet resistance value between the first region and the second region to 20Ω/□ or more, the effect of reducing the in-plane distribution of the voltage drop in the solar cell increases, thereby improving the fill factor of the entire cell and the output characteristics.

To achieve higher efficiency, it is preferable that the concentration distribution in the impurity diffusion layer is low in the first region 2T close to the bus electrodes 7B and high in the second region 2D away from the bus electrodes 7B and that the difference in the sheet resistance between the first region 2T and the second region 2D is about 40Ω/□.

### Example 2

Table 2 represents the measurement results of the solar cell characteristics of the solar cell manufactured on the basis of the second embodiment, as Example 2. In Example 2, the solar cell 10 was manufactured on the basis of the second embodiment.

The boundary between the first region 2T and the second region 2D, which have different impurity concentrations, has a linear shape as illustrated in FIG. 6(a), in which the distance from the grid electrodes 7G increases with distance from the bus electrodes 7B. The boundary between the second region 2D surrounding the grid electrode 7G and the first region 2T intersects with the boundary with the second region 2D surrounding the adjacent grid electrode 7G, at a point furthest away from the bus electrode 7B.

TABLE 2

| SHEET | | | | |
|---|---|---|---|---|
| RESISTANCE | | | SHORT- | |
| OF LIGHT- | | | CIRCUIT | |
| RECEIVING | | | CURRENT | CONVERSION |
| SURFACE | OPEN VOLTAGE | FILL FACTOR | VALUE | EFFICIENCY |
| FIRST | 0.640 | 0.795 | 39.7 | 20.20 |
| REGION: 90 Ω/□ | | | | |
| SECOND | | | | |
| REGION: 50 Ω/□ | | | | |

Table 2 represents the measurement results of the open voltage, fill factor, short-circuit current value, and conversion efficiency in the solar cell in Example 2.

As represented in Table 2, the conversion efficiency is improved compared with the case where the conversion efficiency is the highest in Example 1. This is because the in-plane arrangement of the impurity diffusion layer is performed so as to reduce the in-plane distribution of the voltage drop more than the case of Example 1. When the sheet resistance in the cell plane of the solar cell is uniform, the voltage drop due to the grid electrodes 7G increases with distance from the bus electrodes 7B. However, in Example 2, the distance through which the photogenerated carriers pass in the high-concentration impurity region increases with distance from the bus electrodes 7B. Accordingly, the voltage drop until the carriers are collected in the grid electrodes 7G decreases and the voltage drop distribution in the cell plane of the solar cell decreases, thereby improving the output characteristics.

### Example 3

Table 3 represents the measurement results of the solar cell characteristics of the solar cell manufactured on the basis of the third embodiment, as Example 3. In Example 3, as illustrated in FIG. 7A and FIG. 7B, regions immediately below the bus electrodes 7B and the grid electrodes 7G are designated as the second region 2D, which is the high-concentration region, on the basis of the third embodiment. Other elements were formed in a similar manner to those in the first embodiment.

TABLE 3

| SHEET | | | | |
|---|---|---|---|---|
| RESISTANCE | | | SHORT- | |
| OF LIGHT- | | | CIRCUIT | |
| RECEIVING | | | CURRENT | CONVERSION |
| SURFACE | OPEN VOLTAGE | FILL FACTOR | VALUE | EFFICIENCY |
| FIRST | 0.647 | 0.795 | 39.6 | 20.37 |
| REGION: 90 Ω/□ | | | | |
| SECOND | | | | |
| REGION: 70 Ω/□ | | | | |

Table 3 represents the measurement results of the open voltage, fill factor, short-circuit current value, and conversion efficiency in the solar cell in Example 3.

Furthermore, the sheet resistance in the first region 2T was set to 90Ω/□ and the sheet resistance in the second region 2 was set to 70Ω/□. The conversion efficiency in this case was 20.37%. From the comparison with Table 1, it is found that in the case of Example 3, although the short-circuit current value slightly decreases, the fill factor is improved and the conversion efficiency is improved as compared with Example 1.

As described above, by setting the regions immediately below the bus electrodes 7B and the grid electrodes 7G as the high-concentration second region, the fill factor of the entire cell is improved and thus the output characteristics are improved.

### Example 4

Table 4 represents the measurement results of the solar cell characteristics of the solar cell manufactured on the basis of the fourth embodiment, as Example 4. In Example 4, the solar cell was manufactured on the basis of the fourth embodiment, which has a distribution in the sheet resistance of the translucent conductive film.

As illustrated in FIG. 8A and FIG. 8B, the second translucent conductive film 14D in the second translucent conductive region configured from the translucent conductive film having a low sheet resistance value was formed in the following region. That is, when it is assumed that the interval between the adjacent grid electrodes 7G is W, the second translucent conductive film 14D is formed in a region up to a distance W/4 from the grid electrodes 7G, and when it is assumed that the interval between the bus electrodes 7B is W and the distance from the bus electrodes 7B to the end 1E of the solar cell is W/2, the second translucent conductive film 14D is formed in a region further away by W/4 from the bus electrodes 7B.

TABLE 4

| SHEET | | | | |
|---|---|---|---|---|
| RESISTANCE | | | SHORT- | |
| OF LIGHT- | | | CIRCUIT | |
| RECEIVING | | | CURRENT | CONVERSION |
| SURFACE | OPEN VOLTAGE | FILL FACTOR | VALUE | EFFICIENCY |
| FIRST | 0.710 | 0.783 | 38.7 | 21.51 |
| TRANSLUCENT | | | | |
| CONDUCTIVE | | | | |
| REGION: 90 Ω/□ | | | | |
| SECOND | | | | |
| TRANSLUCENT | | | | |
| CONDUCTIVE | | | | |
| REGION: 90 Ω/□ | | | | |
| FIRST | 0.710 | 0.786 | 38.6 | 21.54 |
| TRANSLUCENT | | | | |
| CONDUCTIVE | | | | |
| REGION: 90 Ω/□ | | | | |
| SECOND | | | | |
| TRANSLUCENT | | | | |
| CONDUCTIVE | | | | |
| REGION: 50 Ω/□ | | | | |

Table 4 represents the measurement results of the open voltage, fill factor, short-circuit current value, and conversion efficiency in the solar cell in Example 4.

As represented in Table 4, the conversion efficiency was improved compared with the case where the translucent conductive film was formed uniformly. As compared with Example 1, the second region formed of the high-concentration diffusion layer is arranged in a region having a large voltage drop and the area of the second region formed of the high-concentration diffusion layer, in which the short-circuit current value is lower than that of the low-concentration diffusion layer, is set to be smaller than the cases of Examples 1 and 2. Accordingly, the fill factor and the conversion efficiency can be improved while suppressing a decrease in the short-circuit current value.

As for Examples 1 to 4 described above, measurement was performed with the same basic structure and a general size. A monocrystalline silicon wafer of the solar cell used in the measurement was manufactured as a substrate, and it was cut into a square size of 10×10 centimeters. The thickness of the wafer was 180 micrometers.

### Example 5

Table 5 represents the measurement results of the characteristics per solar cell in the solar cell module manufactured on the basis of the fifth embodiment. In Example 5, the solar cell module was manufactured on the basis of the modification illustrated in FIG. 11 of the fifth embodiment. The solar cell used was a monocrystalline silicon substrate generally used for the solar cell, having a size of 156×156 millimeters. The thickness of the wafer was 180 micrometers.

FIG. 11 illustrates a string of the solar cell module used in Example 5. The connection portions between the tab wires and the cells are limited only in the corner portions of the solar cells, thereby reducing the shading loss due to a decrease of the light-receiving area of the solar cells 10a to 10c because of the tab wire 20. However, in this case, because the length of the grid electrodes increases as compared with the electrode structure illustrated in FIG. 1. Therefore, an in-plane voltage drop in a portion away from the electrodes 9 for contact with the tab wires increases. Therefore, as illustrated in FIG. 11, a portion close to the electrodes 9 for contact with the tab wires was set as the first region 2T to have a sheet resistance of 90Ω/□, and a portion away from the electrode portions for contact was set as the second region 2D to have a sheet resistance of 50Ω/□. As a comparative example, a solar cell module in which both the first region and the second region have a sheet resistance of 90Ω was also manufactured.

TABLE 5

| SHEET | | | | |
|---|---|---|---|---|
| RESISTANCE | | | SHORT- | |
| OF LIGHT- | | | CIRCUIT | |
| RECEIVING | | | CURRENT | OUTPUT PER |
| SURFACE | OPEN VOLTAGE | FILL FACTOR | VALUE | CELL |
| FIRST | 0.645 V | 0.765 | 9.50 A | 4.67 W |
| REGION: 90 Ω/□ | | | | |
| SECOND | | | | |
| REGION: 90 Ω/□ | | | | |
| FIRST | 0.646 V | 0.772 | 9.48 A | 4.72 W |
| REGION: 90 Ω/□ | | | | |
| SECOND | | | | |
| REGION: 50 Ω/□ | | | | |

As represented in Table 5, the output per solar cell was improved compared with the case where the diffusion layer was formed to have a uniform sheet resistance. This is because, in the electrode structure in FIG. 11, although the in-plane distribution of the voltage drop increases, the voltage drop distribution is reduced by arranging a region having a low sheet resistance in a region having a large voltage drop.

### Example 6

Table 6 represents the measurement results of the characteristics of the solar cell manufactured on the basis of the sixth embodiment. In Example 6, solar cells were manufactured on the basis of the examples illustrated in FIGS. 12A to 12C of the sixth embodiment. The manufactured solar cells were formed by cutting a generally used p-type monocrystalline silicone substrate of 156×156 millimeters longitudinally and horizontally into four equal pieces, thereby forming the solar cells on a silicon substrate having a size of 39×39 millimeters. The thickness of the cut wafer was 180 micrometers. The sheet resistance value of the n-type diffusion layer 2, which is the impurity diffusion layer on the light-receiving surface side of the solar cells, was set to 70Ω/□. As for the electrode, the bus electrode 7B was provided on the side having a high sheet resistance, and the grid electrodes 7G connected to the bus electrode 7B were provided at intervals of 2 millimeters. As a comparative example, a solar cell in a comparative example was manufactured at the same time in which the bus electrode 7B was formed in an inverse relation to Example 6 such that the bus electrode 7B was provided on the side having a low sheet resistance, so as to have a sheet resistance distribution of the substrate in the inverse relation to Example 6.

TABLE 6

| | | | SHORT- | |
|---|---|---|---|---|
| | | | CIRCUIT | CON- |
| | OPEN | FILL | CURRENT | VERSION |
| | VOLTAGE | FACTOR | VALUE | EFFICIENCY |
| EXAMPLE 6 | 0.639 V | 0.788 | 0.594 A | 19.66 |
| COMPAR- | 0.639 V | 0.785 | 0.594 A | 19.58 |
| ATIVE | | | | |
| EXAMPLE | | | | |

As represented in Table 6, the conversion efficiency per solar cell was improved compared with the case where the diffusion layer was formed to have a uniform sheet resistance. This is because, in the electrode structure illustrated in FIGS. 12A and 12B, by arranging the region having a low specific resistance of the substrate in a region having a large voltage drop, as illustrated in FIG. 12C, the in-plane distribution of the voltage drop is reduced.

The present invention is not limited to the structures of the solar cells described in the above embodiments and can be applied to solar cells having other various structures. In the above embodiments, a case where the p-type monocrystalline silicon substrate 1 or the n-type monocrystalline silicon substrate 1n is used as the first-conductivity-type silicon substrate has been described. However, it is sufficient that the silicon substrate is a crystalline silicon substrate, such as a polycrystalline silicon substrate, in addition to the monocrystalline silicon substrate. Further, a solar cell formed by using other types of semiconductor substrates, such as a germanium substrate, a GaAs substrate, or a silicon carbide substrate, can be used. The crystalline silicon substrate includes a monocrystalline silicon substrate and a polycrystalline silicon substrate, and a monocrystalline silicon substrate having a (100) plane as a surface is particularly preferable.

According to the present invention, an effect is obtained where a solar cell having a high fill factor and being capable of improving energy conversion efficiency, a solar cell module, and a manufacturing method of a solar cell can be obtained.

The configuration described in the above embodiments is only an example of the contents of the present invention. The configuration can be combined with other well-known techniques, and it is obvious that the present invention can be configured while modifying it without departing from the scope of the invention, such as omitting a part of the configuration.

What is claimed is:

1. A solar cell comprising:
a first-conductivity-type semiconductor substrate having first and second principal surfaces;
a second-conductivity-type impurity region formed on the first or second principal surface of the semiconductor substrate;
a first collector electrode including a plurality of grid electrodes and a current-collecting portion, the grid electrodes being formed on the first-conductivity-type semiconductor substrate or the second-conductivity-type impurity region, the current-collecting portion connecting the grid electrodes to establish connection to an outside; and
a second collector electrode formed on a side opposing the first collector electrode of the semiconductor substrate, wherein
a sheet resistance of a first collector-electrode forming surface is higher in a first region surrounding the current-collecting portion than a second region away from the current-collecting portion.

2. The solar cell according to claim 1, wherein in the first collector-electrode forming surface, the first-conductivity-type semiconductor substrate or the second-conductivity-type impurity region has a lower impurity concentration in the first region surrounding the current-collecting portion than the second region away from the current-collecting portion.

3. The solar cell according to claim 2, further comprising:
a second-conductivity-type impurity region formed on the first principal surface of the semiconductor substrate;
a first collector electrode including a plurality of grid electrodes and a current-collecting portion, the grid electrodes being formed on the second-conductivity-type impurity region, the current-collecting portion connecting the grid electrodes to establish connection to an outside; and
a second collector electrode formed on the second principal surface side of the semiconductor substrate, wherein
the second-conductivity-type impurity region has a lower impurity concentration in the first region surrounding the current-collecting portion than the second region away from the current-collecting portion.

4. The solar cell according to claim 2, further comprising:
a second-conductivity-type impurity region formed on the first principal surface of the semiconductor substrate;
a first collector electrode including a plurality of grid electrodes and a current-collecting portion, the grid electrodes being formed on the second-conductivity-type impurity region, the current-collecting portion connecting the grid electrodes to establish connection to an outside; and
a second collector electrode formed on the second principal surface side of the semiconductor substrate, wherein
the first-conductivity-type semiconductor substrate has a lower impurity concentration in the first region surrounding the current-collecting portion than the second region away from the current-collecting portion.

5. The solar cell according to claim 2, further comprising:
a second-conductivity-type impurity region formed on the first principal surface of the semiconductor substrate;
a first collector electrode including a plurality of grid electrodes and a current-collecting portion, the grid electrodes being formed on the second principal surface of the semiconductor substrate, the current-collecting portion connecting the grid electrodes to establish connection to an outside; and
a second collector electrode formed on the second-conductivity-type impurity region, wherein
the first-conductivity-type semiconductor substrate has a lower impurity concentration in the first region surrounding the current-collecting portion than the second region away from the current-collecting portion.

6. The solar cell according to claim 3, wherein
the second-conductivity-type impurity region is a second-conductivity-type diffusion layer, and
the current-collecting portion includes a bus electrode formed on the second-conductivity-type diffusion layer to connect the grid electrodes, and has a lower impurity concentration in the first region surrounding the bus electrode than the second region that is away from the bus electrode and includes a peripheral edge portion of the semiconductor substrate.

7. The solar cell according to claim 2, wherein the impurity concentration in the second region becomes higher in a stepwise manner with distance from the bus electrode.

8. The solar cell according to claim 2, wherein the impurity concentration in the second region becomes higher gradually with distance from the bus electrode.

9. The solar cell according to claim 6, wherein the second region surrounds the grid electrodes.

10. The solar cell according to claim 1, wherein a difference in a sheet resistance value between the second region and the first region is equal to or larger than 20 Ω/□.

11. The solar cell according to claim 7, wherein a boundary between the first region and the second region is such that a distance from the grid electrodes increases with distance from the bus electrode.

12. The solar cell according to claim 2, wherein a region immediately below the bus electrode is configured from an impurity region having a higher concentration than the first region.

13. The solar cell according to claim 12, wherein the region immediately below the bus electrode is configured from an impurity region having a concentration equal to a concentration in the second region.

14. The solar cell according to claim 1, comprising:
a translucent conductive film formed on the first-conductivity-type semiconductor substrate or the second-conductivity-type impurity region;
the first collector electrode including the grid electrodes formed on the translucent conductive film and the current-collecting portion that connects the grid electrodes to establish connection to an outside; and
the second collector electrode formed on the second principal surface side of the semiconductor substrate, wherein
the translucent conductive film includes a first translucent conductive film and a second translucent conductive film, the first translucent conductive film constituting a first translucent conductive region surrounding the current-collecting portion, the second translucent conductive film having a lower resistance than the first translucent conductive film and constituting a second translucent conductive region away from the current-collecting portion.

15. The solar cell according to claim 14, wherein
the current-collecting portion includes a bus electrode formed on the second-conductivity-type impurity region to connect the grid electrodes, and
the first translucent conductive film constituting the first translucent conductive region that surrounds the bus electrode is configured from a translucent conductive film having a lower sheet resistance than the second translucent conductive region that is away from the bus electrode and includes a peripheral edge portion of the semiconductor substrate.

16. The solar cell according to claim 15, wherein the first and second translucent conductive films are made of tin oxide and have different tin concentrations from each other.

17. The solar cell according to claim 15, wherein a boundary between the first translucent conductive region and the second translucent conductive region is such that a distance from the grid electrodes increases with distance from the bus electrode.

18. A solar cell module comprising:
the solar cell according to claim 1; and
a tab wire connected to a current-collecting portion of the solar cell.

19. A manufacturing method of a solar cell comprising:
a step of forming a second-conductivity-type impurity region on a first principal surface of a first-conductivity-type semiconductor substrate to form a p-n junction, the first-conductivity-type semiconductor substrate having the first principal surface and a second principal surface;
a step of forming a translucent conductive film on the second-conductivity-type impurity region;
a step of forming, on the translucent conductive film, a first collector electrode including a plurality of grid electrodes and a current-collecting portion that connects the grid electrodes to establish connection to an outside; and
a step of forming a second collector electrode on the second principal surface side of the semiconductor substrate, wherein
the step of forming the translucent conductive film includes a step of forming a first translucent conductive film and a second translucent conductive film, the first translucent conductive film constituting a first translucent conductive region surrounding the current-collecting portion, the second translucent conductive film having a lower resistance than the first translucent conductive film and constituting a second translucent conductive region away from the current-collecting portion.

20. The manufacturing method of a solar cell according to claim 19, wherein
the current-collecting portion includes a bus electrode formed on the second-conductivity-type impurity region to connect the grid electrodes, and
the first translucent conductive film constituting the first translucent conductive region including a portion under the bus electrode is configured from a translucent conductive film having a lower sheet resistance than the second translucent conductive region that is away from the bus electrode and includes a peripheral edge portion of the semiconductor substrate.
